(19) United States
(12) Patent Application Publication
(10) Pub. No.: US 2006/0220740 A1
(43) Pub. Date: Oct. 5, 2006

(54) Apparatus for current measuring and a resistor

(75) Inventors: Yoshiyuki Bessho, Tokyo (JP); Shinichi Tanida, Tokyo (JP)

Correspondence Address: Paul D. Greeley;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/311,068

(22) Filed: Dec. 19, 2005

(30) Foreign Application Priority Data
Mar. 31, 2005 (JP) 2005-100756

(51) Int. Cl. H03F 3/45

(52) U.S. Cl. 330/252

(57) ABSTRACT

A current measuring apparatus using a resistor comprised of a first resistive element: first electrodes disposed on the two ends of the first resistive element; an insulator arranged on the periphery of the first resistive element; a second resistive element arranged on the periphery of the insulator; and second electrodes disposed on the two ends of the second resistive element.

### FIELD OF THE INVENTION

The present invention relates to a resistor, a current measuring apparatus using the resistor, and a method therefor, and more particularly, to a resistor for detecting micro-currents provided with a guard part, a current measuring apparatus using the resistor, and a method therefor.

### DISCUSSION OF THE BACKGROUND ART

One method for measuring the current flowing in a circuit under test is a method that makes current flow in a current detecting resistor, that measures the voltage drop by the resistor, and then calculates the current. When a micro-current is measured by this measurement method, a current detecting resistor having a large resistance must be used to obtain a measurable voltage drop. However, a high-resistance resistor will convert noise components penetrating from the resistor's surroundings into an equivalent voltage. Therefore, to measure with high precision, a guard part must be disposed in order to reduce the external noise surrounding the resistor.

FIG. 2 is a schematic diagram showing the structure of a current measuring apparatus 20 using a guard part 22. The current measuring apparatus 20 is a circuit for measuring the current flowing when the voltage set by a variable voltage source 17 is applied to a circuit under test 18. The current supplied from an operational amplifier 15 passes through a resistor 21, and is supplied to the circuit under test 18. Both ends of the resistor 21 are connected to an operational amplifier 13. A voltage corresponding to the voltage drop in the resistor 21 is output. The output of the operational amplifier 13 is supplied to a voltage measurement and current conversion circuit 14. By measuring the voltage and converting the measured voltage to a current, the current flowing through the resistor 21 is measured.

The resistor 21 is configured from a resistive element 11 and a guard part 22. The guard part 22 is constructed from a metal material that nearly covers most of the periphery of the resistive element 11. The guard part 22 usually has a cylindrical shape, but may be a plate-shaped part disposed parallel to the resistive element 11. The guard part is maintained in a non-contact state with the resistive element 11, and an air layer exists between the resistive element 11 and the guard part 22. The same voltage as the terminal voltage of the resistive element 11 is applied through a buffer 16 to the guard part 22, and an active guard is implemented. Therefore, the potential of the surroundings of the resistive element 11 can be stabilized to the same potential as the voltage at the output end of the resistive element 11. The external noise which has a negative effect on the measurement precision can be greatly reduced.

If the resistor 21 is regarded as a distributed constant circuit, the equivalent circuit can be represented as shown in FIG. 3(a). The resistive element 11 can be represented by an assembly of micro-resistors 30 connected in series. The insulator (air layer) between the resistor 11 and the guard part 22 can be represented by an assembly of micro-capacitors 31 connected in parallel to the micro-resistors 30. When a signal propagates in this type of wire, a time constant proportional to the product of a micro-resistor 30 and a micro-capacitor 31 and a signal propagation delay proportional to the potential difference between the two ends of a micro-capacitor 31 (time lag until the output voltage corresponding to the voltage applied to the input end is stable) are produced. Therefore, until the voltages at both ends of the resistive element 11 to be measured become stable, the time taken is proportional to the delay. The magnitude of this delay becomes the main factor determining the time needed for the measurement.

When the resistance of the resistive element 11 is small, the time until the voltages at both ends of the resistive element 11 are stable is short enough to be ignored in practice because the time constant is small. However, if the resistance of the resistive element 11 increases in order to improve the sensitivity to micro-currents, the delay increases, and a great deal of time is required for measurements. For example, if the resistive element 11 is 1 teraohm, and the sum of the micro-capacitors 31 is 0.1 picofarad, 4.6 seconds wait is necessary until the capacitance is charged to 99% of the final value.

### SUMMARY OF THE INVENTION

A current measuring apparatus comprising a resistor comprised of a first resistive element, first electrodes disposed on both ends of the first resistive element, an insulator arranged on the periphery of the first resistive element, a second resistive element arranged on the periphery of the insulator, and second electrodes disposed on both ends of the second resistive element; a potential application means for applying the same potential as the first electrode opposite to each second electrode; a potential measuring means for measuring the potential of the potential difference between the first electrodes; and a conversion means for converting the potential difference into the current flowing in the resistor.

While maintaining a small effect of external noise and high measurement precision, the potential difference between the two terminals of a micro-capacitor 31 decreases, the signal propagation delay decreases, and fast measurements become possible.

### BRIEF DESCRIPTION OF THE DRAWINGS

FIG. 1 is a schematic diagram of the structure of a current measuring apparatus shown by an embodiment of the present invention.

FIG. 2 is an example of a schematic diagram of the structure of a conventional current measuring apparatus.

FIG. 3 shows equivalent circuits of the resistors illustrated in a conventional example and an embodiment of the present invention.

FIG. 4 is a flow chart of the operation of a current measuring apparatus shown in an embodiment of the present invention.

FIG. 5 shows the structure of the resistor shown in an embodiment of the present invention.

FIG. 6 shows the structure of the resistor shown in another embodiment of the present invention.

FIG. 7 shows the structure of the resistor shown in another embodiment of the present invention.

FIG. 8 shows the structure of the resistor shown in another embodiment of the present invention.

FIG. 9 shows the structure of a signal transmission path shown in an embodiment of the present invention.

### DETAILED DESCRIPTION OF THE PREFERRED EMBODIMENT

Referring to the drawings, typical embodiments of the present invention are explained.

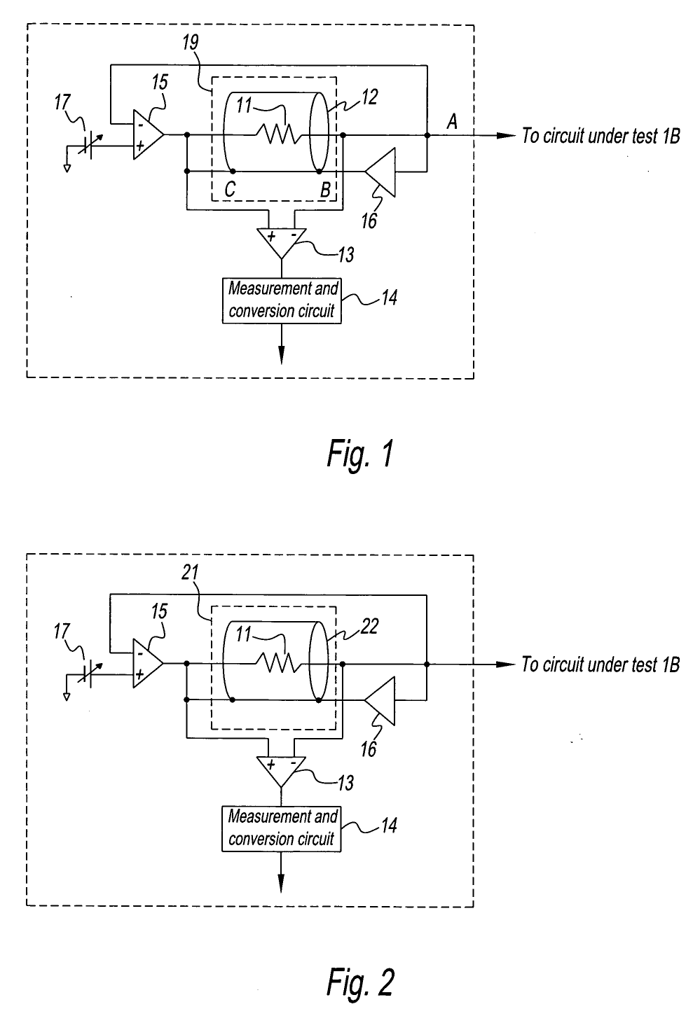

FIG. 1 is a schematic drawing of the structure of a current measuring apparatus 10 related to the present invention. The current measuring apparatus 10 measures the current flowing in the circuit under test 18 when the specified voltage is applied to the circuit under test 18. The current measuring apparatus 10 is comprised of a resistive element 11; a resistor 19 including a guard part 12 covering the periphery of the resistive element 11; an operational amplifier 15 where the inverting input end is connected to the output end of resistive element 11 and the output end is connected to the input end of the resistive element 11; a variable voltage source 17 connected to the non-inverting input end of the operational amplifier 15; a buffer 16 where the input end is connected to the output end of the resistive element 11, and the output end is connected to the guard part 12; an operational amplifier 13 where the inverting and non-inverting input ends are connected to the output end and the input end of the resistive element 11, respectively; and a voltage measurement and current conversion circuit 14 connected to the output end of the operational amplifier 13. One end of the guard part 12 is connected to the output end of the operational amplifier 15, and the other end is connected to the output end of the buffer 16. The circuit under test 18 is connected to the output end of the resistive element 11.

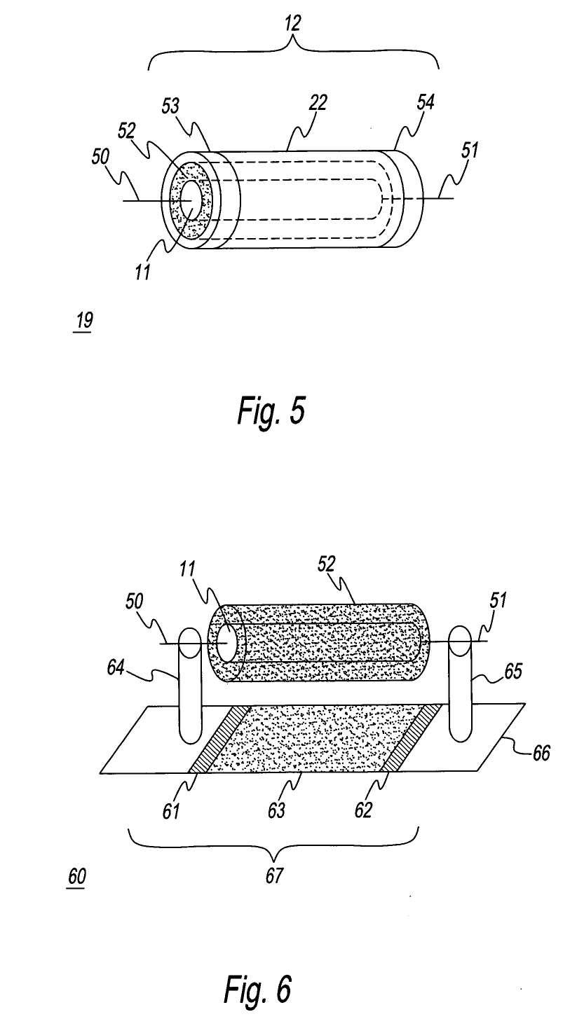

FIG. 5 shows a more detailed structure of a resistor 19. Resistor 19 is comprised of a resistive element 11; electrodes 50, 51 connected to both ends of resistive element 11; an insulator 52 for covering the periphery of the resistive element 11; and a guard part 12 for covering the periphery of the insulator 52. The material for the resistive element 11 of this embodiment is a solid resistive material of carbon or a hardened mixture such as resin (1 teraohm resistance between the electrodes 50, 51). Other materials widely used as the resistive material in commercial resistors, such as metal oxides or cermet may be used. The material of the insulator 52 in this embodiment is an epoxy resin, but other materials widely used as the outer cover material of commercial resistors such as polyimide resins or ceramics may be used. In addition, an air layer is provided between the resistive element 11 and the guard part 12, and air may be used as the insulator 52.

The connection relationships among the electrodes 50, 51, 53, 54 are briefly explained when the resistor in FIG. 5 is connected to the current measuring apparatus 10 in FIG. 1. Electrode 50 and electrode 53 are connected to the output terminal of the operational amplifier 15. Electrode 51 is connected to the input terminal of the buffer 16 and the inverting input terminal of the operational amplifier 15. Electrode 54 is connected to the output terminal of the buffer 16, and the same potential as the output voltage (voltage at point A) of resistive element 11 is applied.

The guard part 12 is comprised of a resistive element 22 and electrodes 53, 54 disposed on both ends thereof. The resistive element 22 of this embodiment is comprised of a semiconducting heat absorbing tube (10⁵Ω·cm volume resistivity) formed from a polyolefin mixture, but may be comprised of another resistive material having a smaller resistivity than the resistive element 11 or by coating a conductive coating such as an EMC coating on the insulator 52. The electrodes 53, 54 are gold leaf, but may be another metal thin film or conductive material. The resistor 19 of this embodiment has cylindrical parts for each structural element of the resistive element 11, insulator 52, and guard part 12, but these parts may have other shapes such as a quadratic prism. The shape of each structural element may differ.

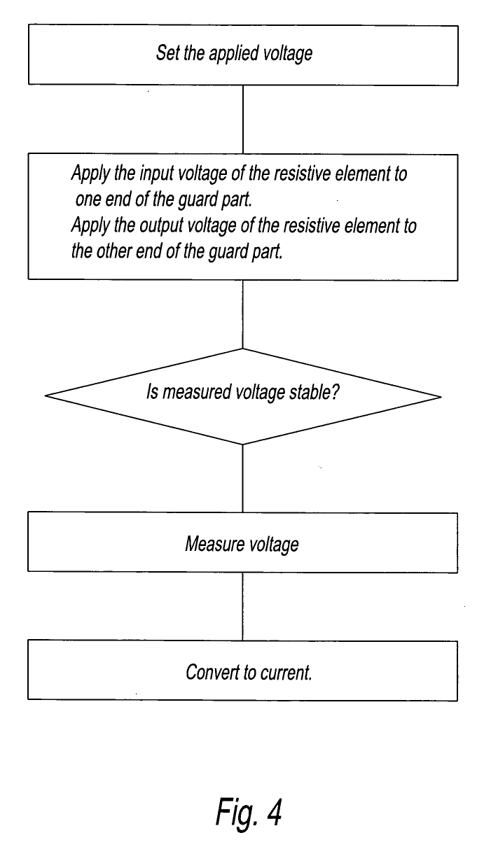

Next, the operation of the current measuring apparatus 10 is explained while referring to the schematic drawing of the structure in FIG. 1 and the flow chart in FIG. 4. First, the output voltage of the variable voltage source 17 is set to the voltage applied to the circuit under test 18 (Step 40). Then the output voltage of the operational amplifier 15 is set so that the potential at point A and the output voltage of the variable voltage source 17 become equal. The output of the operational amplifier 15 is input to the resistive element 11 and is supplied to the electrode 53 of the guard part 12 opposite the input end of the resistive element 11. The same potential as the output voltage of the resistive element 11 (voltage at point A) is applied through the buffer 16 to the electrode 54 (point B) of the guard part 12 opposite the output end of the resistor 19 (Step 41).

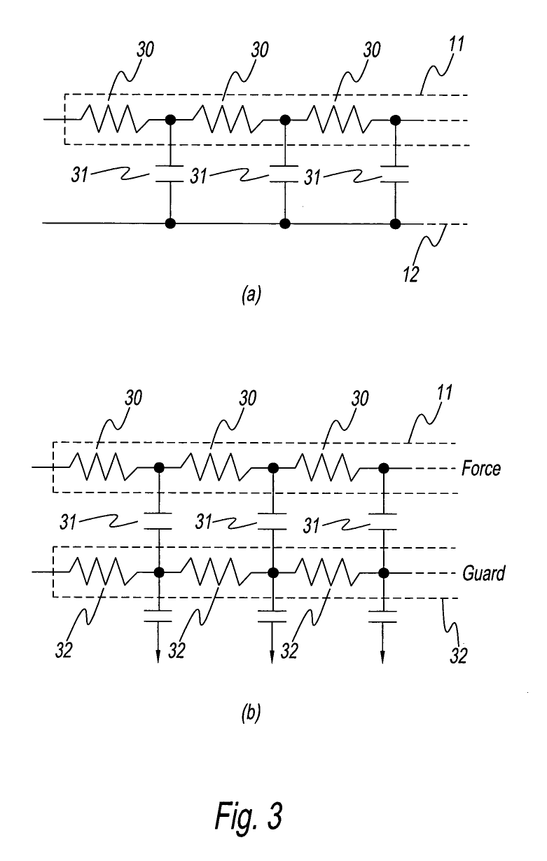

The potential difference between the two ends of the resistive element 11 is output to the output of the operational amplifier 13. The resistor 19 can be represented by an equivalent circuit as shown in FIG. 3(b). In the figure, the resistive element 11 is represented by an assembly of micro-resistors 30, and the resistive element 22 of the guard part 12 by an assembly of micro-resistors 32. The insulator 52 functions as the micro-capacitors 31 connected between the micro-resistors 30, 32. As explained previously, the voltage measurement and current conversion circuit 14 stands by until the output voltage of the operational amplifier 13 is stable (until the potential difference between the two ends of the resistive element 11 is stable) because this kind of distributed constant circuit produces a delay when a signal propagates (Step 42). After it becomes stable, the voltage is measured (Step 43).

Finally, the conversion circuit 14 divides the measured voltage by the resistance of the resistive element 11 to calculate the current of the resistive element 11, that is, the current flowing in the circuit under test 18 (Step 44). The current measuring apparatus 10 comprises an analog-to-digital converter (ADC) in the conversion circuit 14 and an information processor (MPU). The digital value of the analog-to-digital conversion of the measured voltage is calculated, and the current is determined. The conversion method is not limited to this. For example, various other conversion methods such as a method that converts by displaying the measurement result on an analog voltmeter equipped with a character scale covering the current scale can be applied.

The function of the buffer 16 is briefly explained. The conventional current measuring apparatus 20 only has the current generated by external noise flowing. Consequently, the current flowing in the buffer 16 is close to zero. In contrast, the current which is the amount of the voltage between both electrodes of the resistive element 12 divided by the resistance flows in the resistive element 12 of the current measuring apparatus 10. Thus, in order to set the electrode 51 of the output end of the resistive element 11 and the electrode 54 of the output end of the guard part 12 to the same potential, the two are directly connected. By having the current flowing in the guard part 12 flow into the circuit under test 18 and measuring the potential difference between the two ends of the resistive element 11, the current flowing into the circuit under test 18 cannot be measured. Therefore, in this embodiment, by inserting the buffer 16 between electrode 51 and electrode 54, the current flowing in the guard part 12 from the operational amplifier 15 is absorbed by the buffer 16, and the flow into the circuit under test 18 is prevented. In other words, the buffer 16 has the function of setting the electrode 51 on the output end of the resistive element 11 and the electrode 54 on the output side of the guard part 12 to the same potential and the function of preventing the current flowing in the guard 12 from flowing into the circuit under test 18.

The wire in FIG. 3(b), which is an equivalent circuit of the resistor 19, generates a time constant determined by the micro-resistors 30, 32 and micro-capacitors 31 similar to the wire in FIG. 3(a) described previously and a signal propagation delay proportional to the potential difference between the two sides of the micro-capacitor 31. There is no large difference in the time constant as in the case in FIG. 3(a) because the resistance of the resistive element 11 (micro-resistor 30) is substantially larger than the resistance of the resistive element 22 (micro-resistor 32). However, the potential difference between the two ends of a micro-capacitor 31 becomes small because the same potential at both ends of the resistor is applied to each of the two ends of the resistive element 22 of the current measuring apparatus 10. If the voltage gradient between the two ends of both resistors is constant, the potential difference between both ends of a micro-capacitor 31 of the current measuring apparatus 10 should be zero in theory. In an actual apparatus, fabricating a resistor 19 with perfectly matching lengths for the resistive element 11 and the resistive element 22 is difficult. Zero does not result because a perfectly uniform distribution of the resistive material of the resistors 11, 22 is physically impossible. Compared to current measuring apparatus 20, current measuring apparatus 10 has a small signal propagation delay and can perform fast measurements of micro-currents because the potential difference between the two ends of a micro-capacitor 31 becomes significantly smaller. When a voltage displacement that caused the output of the operational amplifier 15 to change in order to obtain the desired measured current was seen as a signal, the signal propagation delay in the resistor 19 appears to be small, and the time needed for the output voltage of the operational amplifier 13 to stabilize becomes short.

FIG. 6 shows another embodiment of a resistor related to the present invention. The resistor 60 in FIG. 6 and the above-mentioned resistor 19 have the same materials and structures for the resistive element 11, insulator 52, and electrodes 50, 51, but the guard part 67 of the resistor 60 differs in that it has a plate-shaped construction. The guard part 67 is formed in a part of the circuit substrate 66 of the current measuring apparatus and is formed from a resistive element 63 having a thin coating of a conductive coating of graphite dissolved in a solution at the position opposite the resistive element 11 coated on the circuit substrate 66, and electrodes 61, 62 affixed as gold leaf on both ends of the resistive element 63. The resistive element 63 may be fabricated by using another conductive coating such as nickel on the substrate 66, and a semiconducting sheet such as a polyolefin compound is affixed to the top of the substrate 66. The electrodes 61, 62 may be made of a thin metal film other than gold leaf, and the conductive coating used in the resistive element 63 may be thickly coated and have high conductivity. The electrodes 50, 51 are supported separately on the substrate 66 by insulating studs 64, 65 formed from polytetrafluoroethylene resin. The studs 64, 65 have coupling surfaces soldered to both ends, and are soldered to the electrodes 50, 51 and the substrate 66.

When the relationships among the parts of resistor 19 and resistor 60 are compared and explained, resistive element 11, insulator 52, and electrodes 50, 51 have common functions. The resistive element 63 has the same function as resistive element 22, and electrodes 61, 62 have the same function as electrodes 53, 54, respectively. Consequently, a current measuring circuit using the resistor 60 can be implemented by replacing the resistor 19 in FIG. 1 with the resistor 60. The measuring operation is the same as the flow chart in FIG. 4 explained earlier.

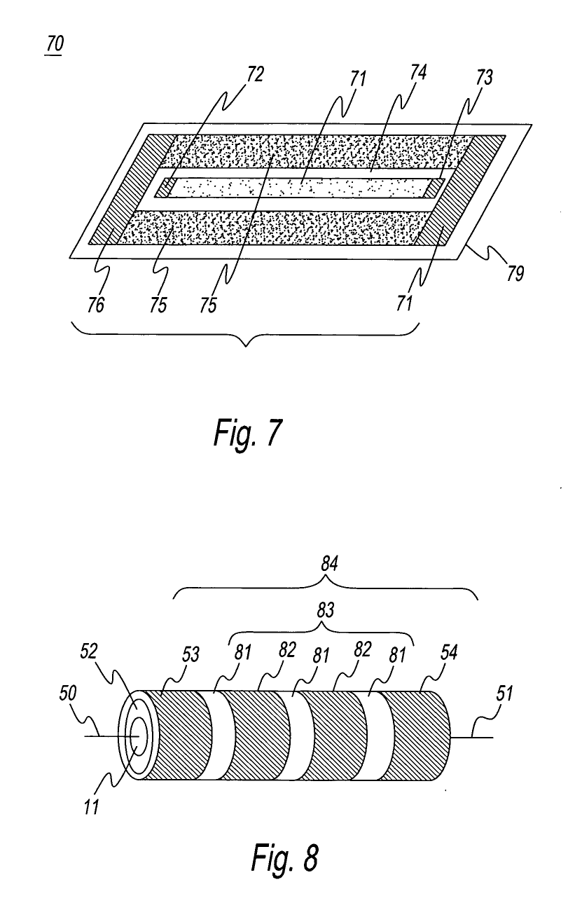

FIG. 7 shows another embodiment of a resistor 70. The resistor 70 is created on a substrate 79. A resistive element 71 is a plate-shaped resistor for detecting current. The resistive element 71 of this embodiment is formed from a cermet material that mixes metal and ceramic, but may be made of another resistive material or a semiconductor such as silicon. Electrodes 72, 73 are disposed on the two ends of the resistive element 71. The electrodes 72, 73 of this embodiment are formed from gold leaf affixed on top of the resistive element 71, and the copper in the surface layer of the circuit substrate 79 can remain and does not need to be etched. An insulator 74 is arranged on the periphery of the resistive element 71. The insulator 74 of this embodiment may be formed by etching the copper surface layer of the circuit substrate 79 and removing only the epoxy resin, which is the substrate material, or by another method that opens a square hole in the substrate for the insulation. A guard part 78 is formed on the periphery of the insulator 74. The guard part 78 is formed from resistive elements 75 formed parallel on both ends of the resistor 71, and electrodes 76, 77 formed on both ends of the resistor 75. The resistive elements 75 of this embodiment are formed by etching and thinning a part of the copper in the surface layer of the substrate 79, but may be formed by coating with a conductive coating. The electrodes 76, 77 are formed by not etching and leaving the copper surface layer of the substrate 79, but also may be formed by another method such as affixing a conductive sheet material.

If the relationships among the parts of the resistor 19 and the resistor 70 are compared and explained, resistive element 11 has the same function as resistive element 71; insulator 52 has the same function as insulator 74; electrode 50 has the same function as electrode 72; electrode 51 has the same function as electrode 73; electrode 53 has the same function as electrode 76; and electrode 54 has the same function as electrode 77. Consequently, by replacing the resistor 19 in FIG. 1 with resistor 70, a current measuring circuit using resistor 70 can be implemented, and the measuring operation has the same flow chart as in FIG. 4 explained earlier.

FIG. 8 shows an embodiment of a different resistor. The resistor 80 in FIG. 8 and the resistor 19 in FIG. 5 have the same materials and structures of resistive element 11, insulator 52, and electrodes 50, 51, 53, 54. A resistive element 83 of a guard part 84 is constructed by alternately disposing a conductive element 82 and a resistive element 81 along the resistive element 11. In other words, a pair of adjacent conductors 82 are mutually disconnected, but are electrically connected by the resistors 81. The resistive element 81 of this embodiment is constructed from a semiconducting tube formed from a polyolefin compound, but can be formed by using another resistive material or a conductive coating. By replacing resistor 19 in FIG. 1 by resistor 80, the current measuring circuit using resistor 80 can be implemented, and the measuring operation is the same as the flow chart in FIG. 4 described earlier.

When the relationships among the parts of resistor 19 and resistor 80 are compared and explained, resistive element 11, insulator 52, and electrodes 50, 51, 53, 54 have common functions. Resistive element 22 has the same function as resistive element 83. Consequently, by replacing resistor 19 in FIG. 1 with resistor 80, a current measuring circuit using resistor 80 can be implemented, and the measuring operation is the same as the flow chart in FIG. 4 described earlier. However, the resistive element 83 of the resistor 80 is not a uniform resistor such as resistive element 22 and combines resistive element 81 with conductive element 82. Therefore, a part of the resistive element 81 becomes the distributed constant circuit shown in FIG. 3(b). A part of the conductive element 82 becomes the distributed constant wire shown in FIG. 3(a). Thus, even if the same voltage is applied to electrode 50 and electrode 53, and electrode 51 and electrode 54, a part is produced where the voltage between the two ends of a micro-capacitor 31 does not become nearly zero. Therefore, the current measuring circuit using resistor 80 has a larger signal propagation delay time compared to the other embodiments. By alternately placing conductive elements 82 and resistive elements 81 as close together as possible, the entire resistive element 83 can have a smaller delay time because the entire resistive element 83 is close to the distributed constant wire in FIG. 3(b).

The technical concepts related to the present invention were explained above in detail while referring to specific embodiments. Clearly, a person skilled in the art in the field of the present invention can add various changes and modifications without departing from the intent and scope of the claims. For example, the resistive element for current detection does not have to be one element, and can be formed by vertically connecting a plurality of resistors having a guard part.

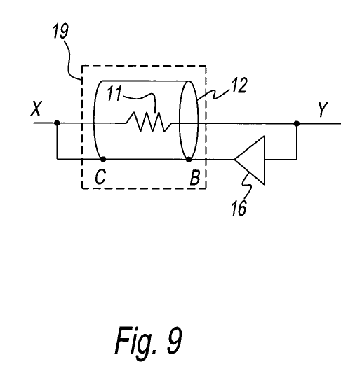

The technique whereby the same potential as the opposite electrode connected to the resistive element for current detection is applied to the electrodes at the two ends of the resistive guard part can be applied to a signal transmission path with a small signal delay. For example, as shown in FIG. 9, by setting the input end of the resistive element 11 of resistor 19 related to the present invention and the input end (point C) of the guard part 12 opposite the input end of resistive element 11 to the same potential and setting the output end of resistive element 11 and the output end (point B) opposite the output end of the resistive element 11 to the same potential, a signal propagation circuit can be implemented with a shielding effect and a small signal propagation delay. The signal propagation path shown in FIG. 9 is the signal propagation path from X to Y. A method setting the same potential to resistive element 11 and guard part 12 can be directly connected or be connected through a buffer 16. When the current flowing in resistive element 11 is preserved as in the current measuring apparatus 20 described earlier and signals are to be transmitted, the output end of the resistive element 11 must be connected through the buffer 16 to the electrode of the guard part or resistive element 12.

Furthermore, the present invention can be applied to a guard method for a resistor where micro-currents flow in a typical electronic circuit. By providing a resistive guard part on the periphery of the resistor, applying the input end voltage of the opposite resistor to the input end of the guard part, and applying the output end voltage of the opposite resistor to the output end of the guard part, a guard method having a shielding effect and a small signal propagation delay can be implemented.

What is claimed is:

1. A resistor which comprises:
a first resistive element;
first electrodes disposed on both ends of said first resistive element;
an insulator arranged on the periphery of said first resistive element;
a second resistive element arranged on the periphery of said insulator; and
second electrodes disposed on both ends of said second resistive element.

2. The resistor of claim 1, wherein said second resistive element is a cylindrical part covering the periphery of said insulator.

3. The resistor of claim 2, wherein said second resistive element is a semiconducting tube.

4. The resistor of claim 1, wherein said second resistive element is a plate-shaped part positioned opposite said first resistive element.

5. The resistor of claim 1, wherein said second resistive element is a part comprising a conductive coating.

6. The resistor of claim 1, wherein said second resistive element comprises:
a plurality of conductors arranged to be in mutually electrically non-connected states; and
a second resistive element electrically connected to said adjacent conductors.

7. The resistor of claim 1, wherein at least a portion of said insulator is formed from air.

8. A resistor which comprises:
a first resistive element;
first electrodes disposed on both ends of said first resistive element;
a resistive guard part arranged on the periphery of said first resistive element to be in a non-contact state with said first resistive element; and
second electrodes disposed on both ends of said resistive guard part.

9. The resistor of claim 8, wherein said resistive guard part is a cylindrical part covering the periphery of said first resistive element.

10. The resistor of claim 9, wherein said resistive guard part is a semiconducting tube.

11. The resistor of claim 8, wherein said resistive guard part is a plate-shaped part arranged to be opposite said first resistive element.

12. The resistor of claim 8, wherein said resistive guard part is a part covered by a conductive coating.

13. The resistor of claim 8, wherein said resistive guard part comprises:
a plurality of conductors arranged to be in mutually electrically non-connected states; and
a third resistive element electrically connected to said adjacent conductors.

14. A current measuring apparatus which comprises:
a first resistive element;
first electrodes disposed on the two ends of said first resistive element;
an insulator arranged on the periphery of said first resistive element;
a second resistive element arranged on the periphery of said insulator;
second electrodes disposed on the two ends of said second resistive element;
a voltage source that applies the same potential to said opposite first electrodes to said second electrodes;
a potentiometer that measures the potential difference between said first electrodes; and
a converter that converts said potential difference to the current flowing in said first resistive element.

15. A current measuring apparatus which comprises:
a resistive element;
first electrodes disposed on the two ends of said resistive element;
a resistive guard part arranged on the periphery of said resistive element and has an electrically non-conducting state with said resistive element;
second electrodes disposed on the two ends of said resistive guard part;
a voltage source that applies the same potential as said opposite first electrodes to said second electrodes;
a potentiometer that measures the potential difference between said first electrodes; and
a converter that converts said potential difference to the current flowing in said resistive element.

16. The current measuring apparatus of claim 15, wherein at least a portion of said potentiometer is constructed from a buffer.

17. The current measuring apparatus of claim 16, wherein said buffer is connected between the output end of said resistive element and one end of said resistive guard part opposite said output end.

18. A method that provides a resistive element and a guard part and measures the current flowing in said resistive element, said method comprising:
applying the same potential as the input end of said resistive element to one end of said guard part opposite the input end of said resistive element;
applying the same potential as the output end of said resistive element to the other end of said guard part opposite the output end of said resistive element; and
measuring the potential difference between the two ends of said resistive element; and
determining said current from said potential difference.

19. A signal transmission path which comprises:
a first resistive element;
first electrodes disposed on the two ends of said first resistive element;
an insulator arranged on the periphery of said first resistive element;
a second resistive element arranged on the periphery of said insulator;
second electrodes disposed on both ends of said second resistive element; and
a voltage source that applies the same potential as said opposite first electrodes to said second electrodes.

20. A signal transmission path which comprises:
a resistive element;
first electrodes disposed on the two ends of said resistive element;
a resistive guard part arranged on the periphery of said resistive element to be in an electrically non-conducting state with said resistive element;
second electrodes disposed on the two ends of said resistive guard part; and
a voltage source that applied the same potential as said opposite first electrodes to said second electrodes.

21. A guard configuration which comprises:
a second resistive element arranged on the periphery of a first resistive element;
guard parts having electrodes disposed on the two ends of said second resistive element; and
a voltage source that applies the same potential as the voltage of both ends of said opposite first resistive element to said electrodes.
